(19) United States
(12) Patent Application Publication
(10) Pub. No.: US 2013/0220959 A1
(43) Pub. Date: Aug. 29, 2013

(54) HOIST APPARATUS AND HOIST SYSTEM THEREOF

(71) Applicant: SAMSUNG ELECTRONICS CO., LTD., (US)

(72) Inventors: Yu-dong WON, Suwon-si (KR); Jong-in LEE, Seoul (KR); Min-gu CHANG, Anyang-si (KR); Seung-jun LEE, Yongin-si (KR)

(73) Assignee: SAMSUNG ELECTRONICS CO., LTD., Suwon-si (KR)

(21) Appl. No.: 13/731,517

(22) Filed: Dec. 31, 2012

(30) Foreign Application Priority Data
Feb. 28, 2012 (KR) 10-2012-0020405

(51) Int. Cl. B66C 19/00; B66C 13/18; H01L 21/677

(52) U.S. Cl. CPC B66C 19/00; H01L 21/67763; B66C 13/18
USPC 212/276; 212/330; 254/266

(57) ABSTRACT

A hoist apparatus including a traveling unit that travels from one place to another, an elevating unit installed in the traveling unit to be lifted up and lowered down from the traveling unit, a grip device which is installed in the elevating unit and selectively grips a stumbling projection formed at one side of an accommodating container accommodating an object, and a separation preventing apparatus which is connected to the elevating unit and selectively closes an open inlet of the accommodating container so that the object accommodated in the accommodating container is not separated from the accommodating container.

### CROSS-REFERENCE TO RELATED APPLICATIONS

This application claims priority from Korean Patent Application No. 10-2012-0020405, filed on Feb. 28, 2012, in the Korean Intellectual Property Office, the disclosure of which is incorporated herein in its entirety by reference.

### BACKGROUND

Apparatuses consistent with exemplary embodiments relate to a semiconductor hoist apparatus and a hoist system including the semiconductor hoist apparatus, and more particularly, to a hoist apparatus that lifts up an accommodating container accommodating an object and transfers the accommodating container to another location along a rail and a hoist system including the hoist apparatus.

In general, hoists refer to apparatuses for lifting up and transferring an object. Hoists are used for transporting freights in a storehouse, a railway station, or the like, assembling and disassembling machines, etc. Also, hoists are used for transferring semiconductor distributions.

### SUMMARY

One or more exemplary embodiments provide a hoist apparatus which may safely and accurately transfer an object, such as a lead frame, a printed circuit board, or a ring, accommodated in an accommodating container, such as a magazine or a ring cassette, while preventing the object from being removed from the accommodating container, and a hoist system including the hoist apparatus.

According to an aspect of an exemplary embodiment, there is provided a hoist apparatus including: a traveling unit that travels from one place to another; an elevating unit installed in the traveling unit to be lifted up and lowered down from the traveling unit; a grip device which is installed in the elevating unit and selectively grips a stumbling projection formed at one side of an accommodating container accommodating an object; and a separation preventing apparatus which is connected to the elevating unit and selectively closes an open inlet of the accommodating container so that the object accommodated in the accommodating container is not separated from the accommodating container.

The grip device may include: a grip finger formed to have a shape corresponding to the stumbling projection of the accommodating container; a grip arm connected to the grip finger; and a grip driving device for selectively moving the grip arm toward the accommodating container.

The grip driving device may include: a grip driving motor installed in the elevating unit; a screw rod rotated by the grip driving motor; a movable body which moves forward and backward along the screw rod; a cam member which is installed at one side of the movable body to move forward and backward together with the movable body and includes an inclined guiding surface in a direction in which the movable body moves forward and backward; and a carriage which is installed in the elevating unit to move toward the accommodating container and includes a rod contacting a guiding surface of the cam member, wherein the grip arm is installed at one side of the carriage.

The grip device further may include: a grip sensor which senses an engagement state between the grip finger and the stumbling projection; and a controller which receives a grip state signal from the grip sensor and applies a control signal to the elevating driving apparatus for lifting up and lowering down the elevating unit.

The hoist apparatus may further include an aligning device which is installed in the elevating unit and which aligns the accommodating container to a regular position.

The aligning device may include an aligning protrusion inserted into an aligning hole formed at another side of the accommodating container.

The aligning device may further include: a fixing stage installed in the elevating unit; an aligning movable stage installed in the fixing stage to be lifted up and lowered down, wherein the aligning protrusion is installed in the aligning movable stage; and; a spring installed between the fixing stage and the aligning movable stage.

The aligning device may further include: an aligning sensor which senses an alignment state of the elevating unit and the aligning device; and a controller which receives an alignment state signal from the aligning sensor and applies a control signal to the elevating driving apparatus for lifting up and lowering down the elevating unit.

The hoist apparatus may further include the elevating driving apparatus which is installed in the traveling unit and lifts up and lowers down the elevating unit, wherein the elevating driving apparatus comprises: a pulley which winds up a belt installed in the elevating unit; and an elevating driving motor which rotates the pulley.

The separation preventing apparatus may include a separation preventing rod which is fixed at one side of the grip arm connected to the grip finger formed to have a shape corresponding to the stumbling projection of the accommodating container and moves toward the open inlet of the accommodating container together with the grip arm when the grip device grips the stumbling projection.

The separation preventing apparatus may include: a link of which one end is hinge-coupled to the cam member; a rotating rod of which one end portion is coupled to another end of the link and another end portion is rotated about a rotation axis; and a separation preventing rod which is installed in the rotating rod and is rotated toward the open inlet of the accommodating container by the rotating rod.

The object may be a lead frame for a semiconductor or a printed circuit board (PCB) for a semiconductor, and the accommodating container may be a magazine for accommodating the lead frame or the PCB.

The object may be a ring for transferring a semiconductor, and the accommodating container may be a ring cassette for accommodating the ring.

A guide pin inserted into a guide hole formed in the traveling unit may be installed the elevating unit.

According to another aspect of another exemplary embodiment, there is provided a hoist system including: a port in which an accommodating container accommodating an object is disposed; and a hoist apparatus which transfers the accommodating container disposed in the port to another location, wherein the hoist apparatus comprises: a traveling unit which travels from one place to another; an elevating unit installed in the traveling unit to be lifted up and lowered down according to the traveling unit; a grip device which is installed in the elevating unit and selectively grips a stumbling projection formed at one side of the accommodating container accommodating an object; and a separation preventing apparatus which is connected to the elevating unit and selectively closes an opened inlet of the accommodating container so that the object accommodated in the accommodating container is not separated from the accommodating container.

### BRIEF DESCRIPTION OF THE DRAWINGS

Exemplary embodiments of the inventive concept will be more clearly understood from the following detailed description taken in conjunction with the accompanying drawings, in which:

FIG. 1 is a perspective view showing a grip preparation state of a hoist apparatus and a hoist system including the hoist apparatus according to an exemplary embodiment;

FIG. 2 is a perspective view showing a grip completion state of the hoist apparatus and the hoist system of FIG. 1, according to an exemplary embodiment;

FIG. 3 is a perspective view showing a traveling state of the hoist apparatus and the hoist system of FIG. 1, according to an exemplary embodiment;

FIG. 4 is a cross-sectional side view of a traveling unit and an elevating unit of the hoist apparatus of FIG. 1, according to an exemplary embodiment;

FIG. 5 is a cross-sectional view showing a grip preparation state of a grip driving device of FIG. 1 taken along a line V-V of FIG. 1, according to an exemplary embodiment;

FIG. 6 is a cross-sectional view showing the grip preparation state of the grip driving device of FIG. 1 taken along a line VI-VI of FIG. 1, according to an exemplary embodiment;

FIG. 7 is a plan view showing a grip preparation state of a separation preventing rod and an accommodating container of the grip driving device of FIG. 1, according to an exemplary embodiment;

FIG. 8 is a cross-sectional view showing a grip completion state of the grip driving device of FIG. 2 taken along a line VIII-VIII, according to an exemplary embodiment;

FIG. 9 is a cross-sectional view showing the grip completion state of the grip driving device of FIG. 2 taken along a line IX-IX, according to an exemplary embodiment;

FIG. 10 is a plan view showing a grip completion state of the separation preventing rod and the accommodating container of the grip driving device of FIG. 2, according to an exemplary embodiment;

FIG. 11 is a cross-sectional view showing a grip preparation state of a grip driving device according to another exemplary embodiment;

FIG. 12 is a cross-sectional view showing the grip preparation state of the grip driving device of FIG. 11, according to an exemplary embodiment;

FIG. 13 is a plan view showing a grip preparation state of a separation preventing rod and an accommodating container of the grip driving device of FIG. 11, according to an exemplary embodiment;

FIG. 14 is a cross-sectional view showing a grip completion state of a grip driving device according to another exemplary embodiment;

FIG. 15 is a cross-sectional view showing the grip completion state of the grip driving device of FIG. 14;

FIG. 16 is a plan view showing a grip completion state of a separation preventing rod and an accommodating container of the grip driving device of FIG. 14; and

FIG. 17 is a plan view showing a separation preventing rod and an accommodating container of a hoist apparatus according to another exemplary embodiment.

### DETAILED DESCRIPTION OF THE EXEMPLARY EMBODIMENTS

The inventive concept will be described more fully with reference to the accompanying drawings.

The inventive concept may, however, be embodied in many different forms and should not be construed as limited to the exemplary embodiments set forth herein. Rather, these embodiments are provided so that this disclosure will be thorough and complete, and will fully convey the scope of the inventive concept to those skilled in the art. In the drawings, lengths and sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the inventive concept.

Spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

As such, variations from the shapes of the illustrations as a result, for example, of manufacturing techniques and/or tolerances, are to be expected. Thus, the embodiments described herein should not be construed as limited to the particular shapes of regions illustrated herein but are to include deviations in shapes that result, for example, from manufacturing.

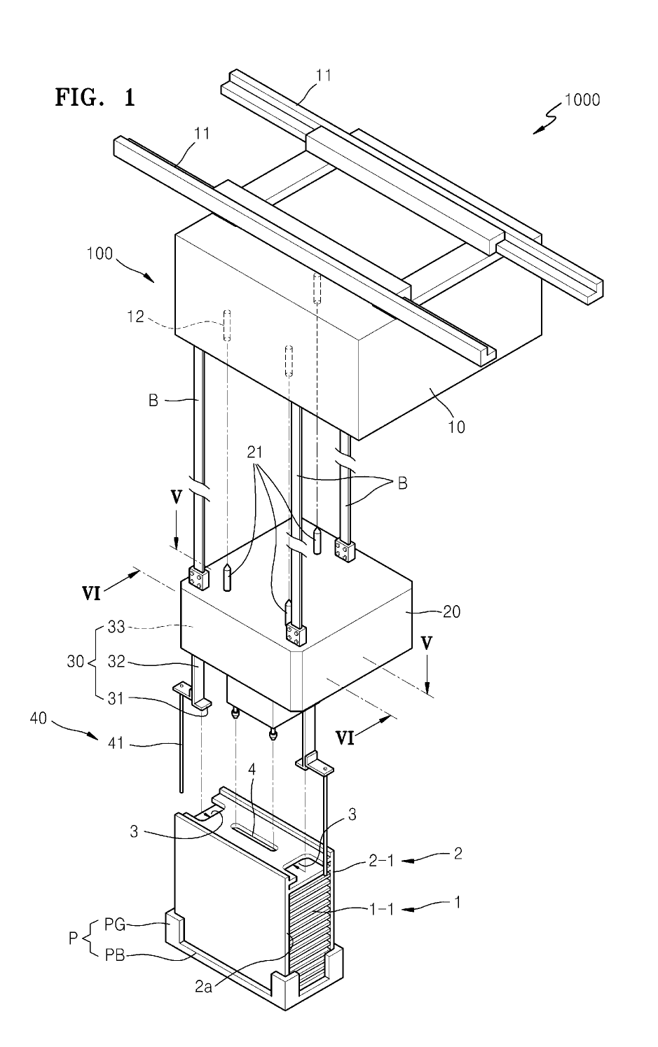

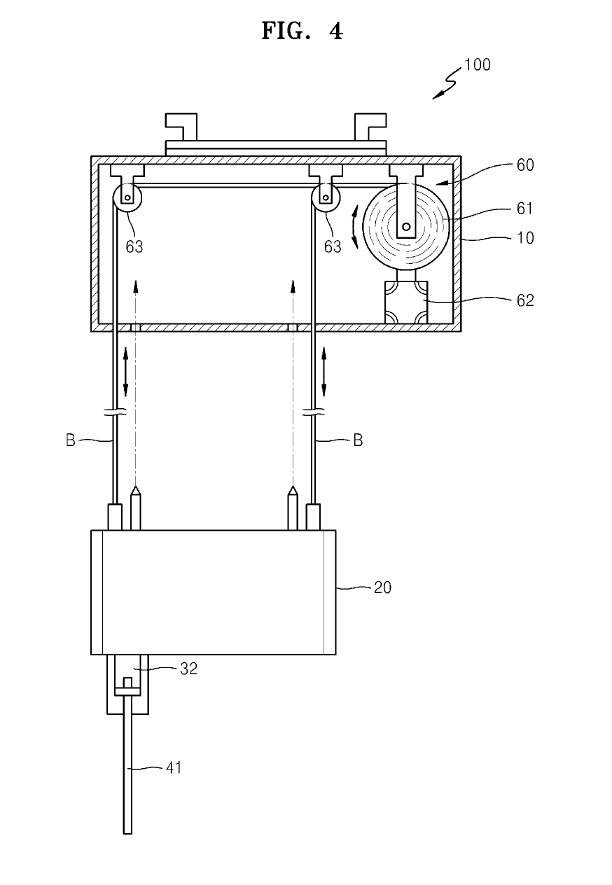

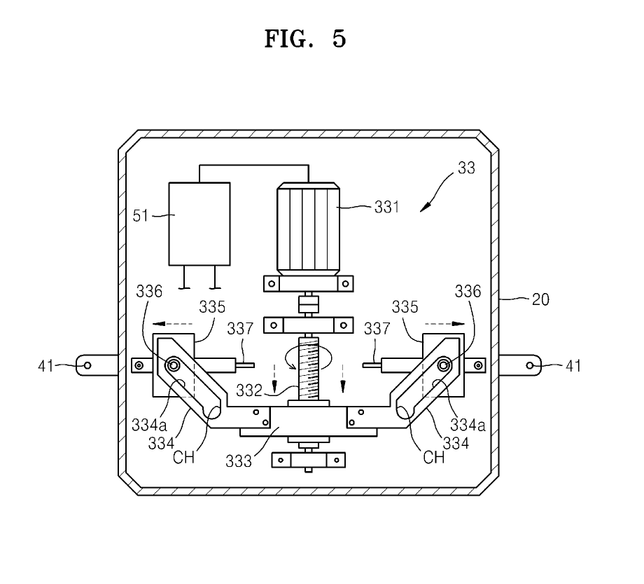

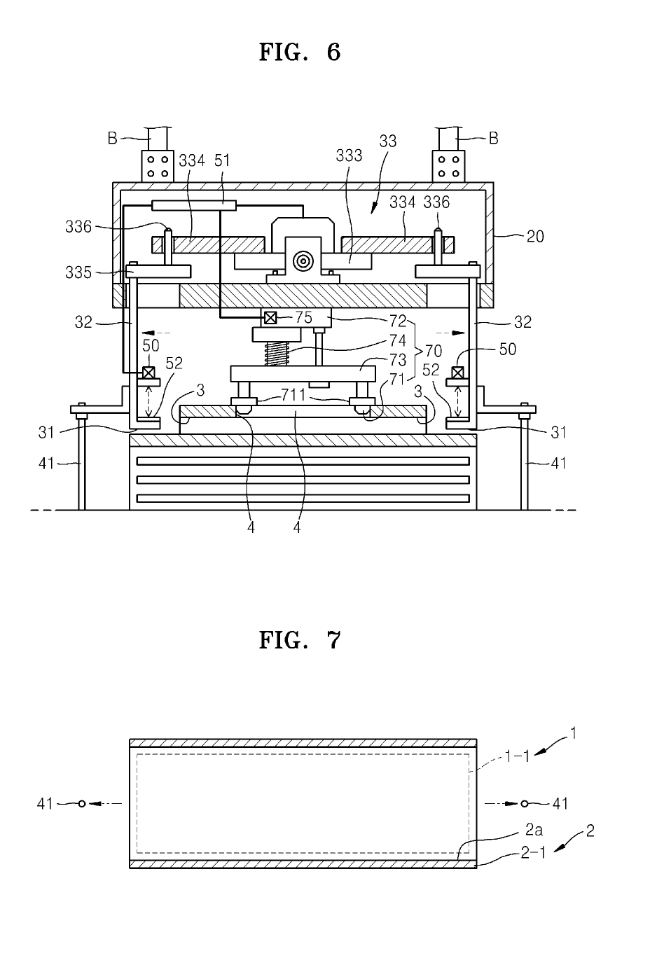

FIG. 1 is a perspective view showing a grip preparation state of a hoist apparatus 100 and a hoist system 1000 including the hoist apparatus 100 according to an exemplary embodiment. FIG. 4 is a cross-sectional side view of a traveling unit 10 and an elevating unit 20 of the hoist apparatus 100 of FIG. 1. FIG. 5 is a cross-sectional view showing a grip preparation state of a grip driving device 33 of FIG. 1 taken along a line V-V of FIG. 1. FIG. 6 is a cross-sectional view showing the grip preparation state of the grip driving device 33 of FIG. 1 taken along a line VI-VI of FIG. 1. FIG. 7 is a plan view showing a grip preparation state of a separation preventing rod 41 and an accommodating container 2 of the grip driving device 33 of FIG. 1.

As shown in FIGS. 1 and 4 to 7, the hoist apparatus 100 may roughly include the traveling unit 10, the elevating unit 20, a grip device 30, a separation preventing apparatus 40, an elevating driving apparatus 60, and an aligning device 70.

As shown in FIG. 1, the traveling unit 10 travels along a rail 11. The rail 11 may be mainly installed along a predetermined route on a ceiling of a semiconductor line or on a ceiling, in the air, or on a wall surface of a factory, and may be installed above a first port P in which the accommodating container 2 accommodating an object 1 is disposed and above a second port (not shown). Thus, the traveling unit 10 may move to the first port P and the second port upward while traveling along the rail 11. A traveling apparatus for driving the traveling unit 10 may be a traveling driving apparatus that is configured in any of well-known various forms, for example, a traveling wheel that is driven by a motor receiving power via the rail 11 or an electrical line, and a detailed description thereof will be omitted here.

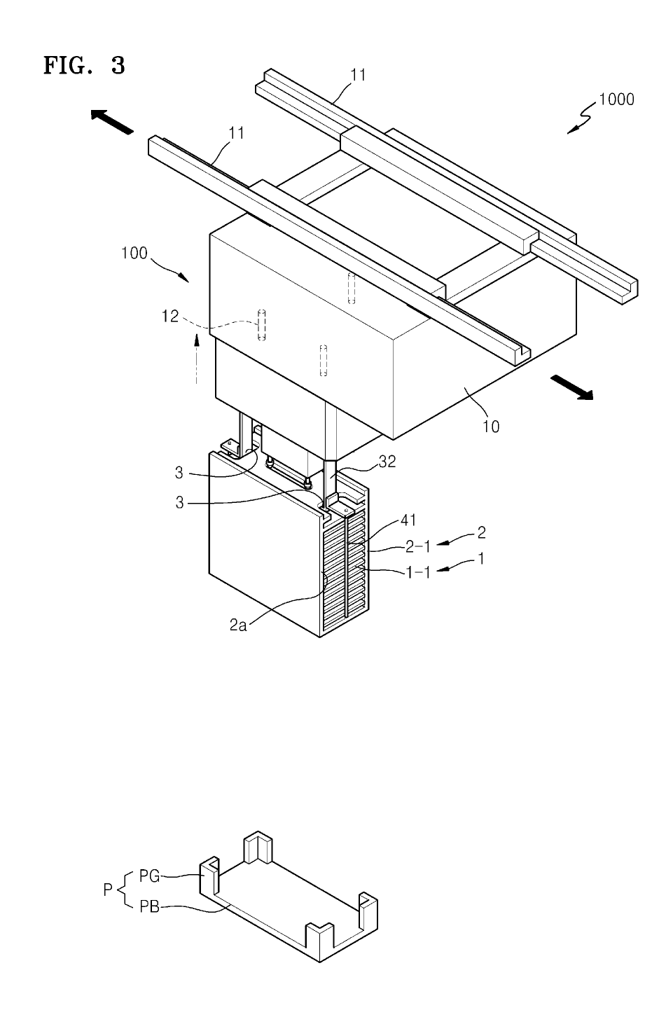

Also, the elevating unit 20 may be installed in the traveling unit 10 to be lifted up and lowered down from the traveling unit 10. That is, the traveling unit 10 may be used here as a base unit of the elevating unit 20. Here, as shown in FIGS. 1 to 4, a plurality of guide pins 21 may be respectively inserted into a plurality of guide holes 12 formed in the traveling unit 10 and may be installed in the elevating unit 20. Accordingly, as shown in FIGS. 3 and 4, if the elevating unit 20 ascends due to the elevating driving apparatus 60 until the elevating unit 20 reaches the traveling unit 10, the guide pins 21 may be respectively inserted into the guide holes 12 formed in the traveling unit 10, and thus, the elevating unit 20 and the traveling unit 10 may be firmly coupled to each other. In this state, the elevating unit 20 and the traveling unit 10 together may be stably moved to another port without being shaken.

As shown in FIG. 1, the grip device 30 may be installed in the elevating unit 20 and may selectively grip a stumbling projection 3 formed at one side of the accommodating container 2 accommodating the object 1. The grip device 30 may include a grip finger 31, a grip arm 32, and the grip driving device 33.

Here, as shown in FIG. 6, the grip finger 31 may be formed to have a shape corresponding to the stumbling projection 3 to lift up the stumbling projection 3 of the accommodating container 2. In other words, the grip finger 31 may protrude in a horizontal direction to contact the stumbling projection 3.

Also, the grip arm 32 is connected to the grip finger 31 and may be formed to vertically extend upward.

As shown in FIGS. 5 and 6, the grip driving device 33 may selectively move the grip arm 32 toward the accommodating container 2, and include a grip driving motor 331, a screw rod 332, a movable body 333, a cam member 334, and a carriage 335.

As shown in FIGS. 5 and 6, the grip driving motor 331 is installed in the elevating unit 20 to rotate the screw rod 332, and the screw rod 332 is axially rotated by the grip driving motor 331. Also, the movable body 333 passes in a threaded manner on the screw rod 332 to move forward and backward along the screw rod 332.

Also, the cam member 334 is installed at one side of the movable body 333 to move forward and backward together with the movable body 333 and includes a cam hole CH including an inclined guiding surface 334a in a direction in which the movable body 333 moves forward and backward.

The carriage 335 is installed in the elevating unit 20 along a guide 337 to freely move toward the accommodating container 2. The carriage 335 includes a rod 336 passing through the cam hole CH including the inclined guiding surface 334a of the cam member 334, and the grip arm 32 is installed at one side of the carriage 335.

Accordingly, if the grip driving motor 331 positively or reversely rotates the screw rod 332, the movable body 333 may move forward and backward along the screw rod 332, the rod 336 and the carriage 335 may reciprocate in the cam hole CH along the guiding surface 334a, and the grip finger 31 connected to the grip arm 32 may move forward and backward toward the stumbling projection 3 to grip or release the accommodating container 2.

Also, the separation preventing apparatus 40 is connected to the elevating unit 20 and selectively closes an open inlet 2a of the accommodating container 2 so that the object 1 accommodated in the accommodating container 2 is not separated from the accommodating container 2.

As shown in FIGS. 1 to 10, the separation preventing apparatus 40 may be the separation preventing rod 41, which is fixed at one side of the grip arm 32. Accordingly, as shown in FIG. 7, when the grip device 30 is in a preparation state where the grip device 30 releases the stumbling projection 3 without gripping the stumbling projection 3, the separation preventing rod 41 may move in a direction away from the open inlet 2a of the accommodating container 2.

Meanwhile, as shown in FIGS. 5 and 6, the hoist apparatus 100 may further include a grip sensor 50 and a controller 51.

Here, the grip sensor 50 is a sensor for sensing an engagement state between the grip finger 31 and the stumbling projection 3, and may be an optical sensor for emitting light to a reflection layer 52 installed on one surface of the grip finger 31 and sensing light reflected by the reflection layer 52. The reflection layer 52 may be formed by using various methods, for example, by attaching a reflection tape to the grip finger 31 or forming a reflection layer on the grip finger 31. The reflection layer 52 is not formed in the stumbling projection 3.

The controller 51 receives a grip state signal from the grip sensor 50 and applies a control signal to the elevating driving apparatus 60 for lifting up and lowering down the elevating unit 20.

Accordingly, as shown in FIG. 6, if the stumbling projection 3 is not between the grip sensor 50 and the reflection layer 52, the grip sensor 50 may apply a grip preparation state signal to the controller 51.

As shown in FIG. 6, the aligning device 70 is installed in the elevating unit 20 and aligns the accommodating container 2 to a regular position. The aligning device 70 may include an aligning protrusion 71, a fixing stage 72, an aligning movable stage 73, a spring 74, and an aligning sensor 75.

Here, the aligning protrusion 71 is inserted into an aligning hole 4 formed at another side of the accommodating container 2. A leading end of the aligning protrusion 71 may be formed to be pointed or may have a round protrusion shape. A stopper 711 having a flange shape and engaging with the aligning hole 4 may be formed in a posterior end of the aligning protrusion 71.

Also, the fixing stage 72 is installed in the elevating unit 20, and may have a space therein. One end of the movable stage 73 may be inserted into the space so as to be lifted up toward or lowered down from the fixing stage 72, and the aligning protrusion 71 may be installed in another end of the movable stage 73. The spring 74 is installed between the fixing stage 72 and the aligning movable stage 73, and thus, a restoring force is applied when the movable stage 73 is away from the fixing stage 72.

The aligning sensor 75 is installed in the fixing stage 72 to sense an alignment state of the elevating unit 20 and the aligning device 70 and to sense movement of the aligning movable stage 73. Here, the aligning sensor 75 may be a touch switch sensor that is touched due to movement of the movable stage 73, an optical sensor, a magnetic sensor, or the like.

Accordingly, as shown in FIG. 6, when the elevating unit 20 descends, the aligning protrusion 71 is inserted into the aligning hole 4 of the accommodating container 2, and then, when the stopper 711 engages with the aligning hole 4, the movable stage 73 ascends, and the aligning sensor 75 having sensed movement of the movable stage 73 applies an alignment completion signal, and thus, the controller 51 may apply a descend stop control signal to the elevating driving apparatus 60 for lifting up and lowering down the elevating unit 20.

As shown in FIG. 4, the elevating driving apparatus 60 is installed in the traveling unit 10, and lifts up and lowers down the elevating unit 20. The elevating driving apparatus 60 may include a pulley 61 for winding up a belt B installed in the elevating unit 20, an elevating driving motor 62 for rotating the pulley 61, and a reversing pulley 63 for reversing a direction of the belt B. Here, although FIG. 4 shows the elevating driving apparatus 60 including only the pulley 61 for winding up the belt B, the elevating driving apparatus 60 may be any of various driving apparatuses, for example, a sprocket assembly for winding up various chains, a rack and pinion assembly, a linear motor assembly, a wire pulley assembly, a cam assembly, or the like.

Meanwhile, as shown in FIGS. 1 and 7, the object 1 may be a lead frame for a semiconductor or a printed circuit board (PCB) for a semiconductor 1-1, and the accommodating container 2 may be a magazine 2-1 for accommodating the lead frame or the PCB 1-1. Here, the object 1 may be injected into or discharged from the accommodating container 2 through the open inlet 2a of the accommodating container 2, and may be formed at two sides of the magazine 2-1 as shown in FIG. 7.

Also, as shown in FIG. 1, the hoist system 1000 may include a port base PB in which the accommodating container 2 accommodating the object 1 is disposed, a port guide PG for guiding the accommodating container 2, and the above-described hoist apparatus 100.

Hereinafter, operations of the hoist apparatus 100 and the hoist system 1000 including the hoist apparatus 100 will be described in detail.

As shown in FIG. 1, when the traveling unit 10 reaches a point above the port P in which the accommodating container 2 is disposed, the pulley 61 of the elevating driving apparatus 60 is positively rotated by the elevating driving motor 62, and at the same time, the belt B is unwound, and thus, the elevating unit 20 descends as shown in FIG. 4.

Next, as shown in FIG. 6, when the aligning movable stage 73 moves at the same time as insertion of the aligning protrusion 71 into the aligning hole 4 of the accommodating container 2, the aligning sensor 75 senses this and applies an alignment completion signal to the controller 51, and the controller 51 applies a descend stop control signal to the elevating driving apparatus 60 for lifting up and lowering down the elevating unit 20 to stop descending of the elevating unit 20.

At this time, when the grip driving motor 331 positively rotates the screw rod 332 and the movable body 333 moves forward along the screw rod 332, the guiding surface 334a is moved in a direction away from a pair of the carriages 335 as the pair of carriages 335 are moved away from each other while carrying out a cam action of the cam hole CH, and thus, the grip finger 31 connected to the grip arm 32 may move in a direction away from the stumbling projection 3, thereby being ready to release the accommodating container 2.

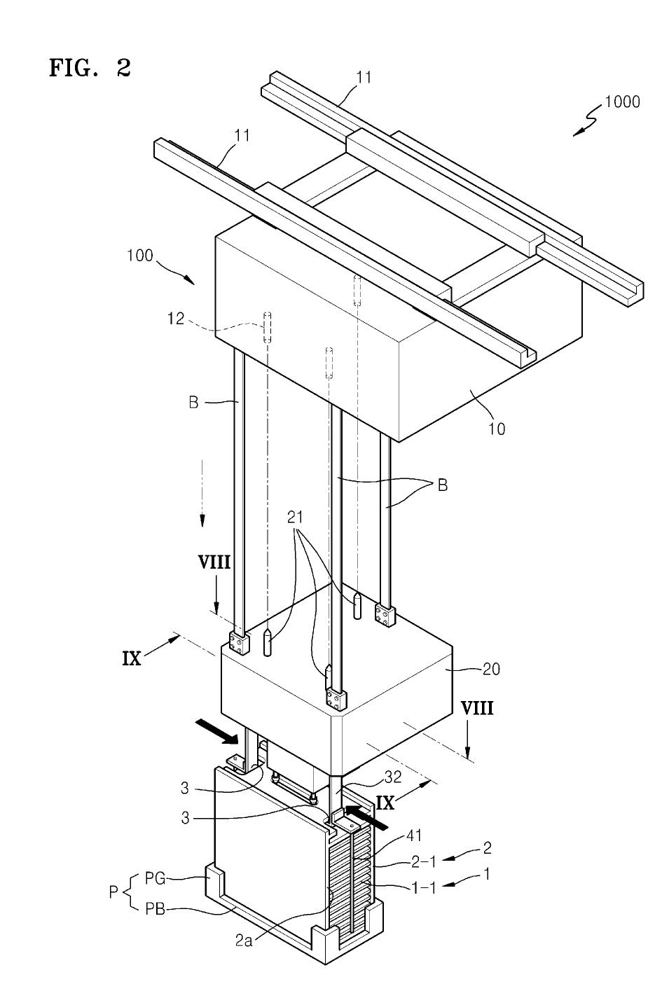

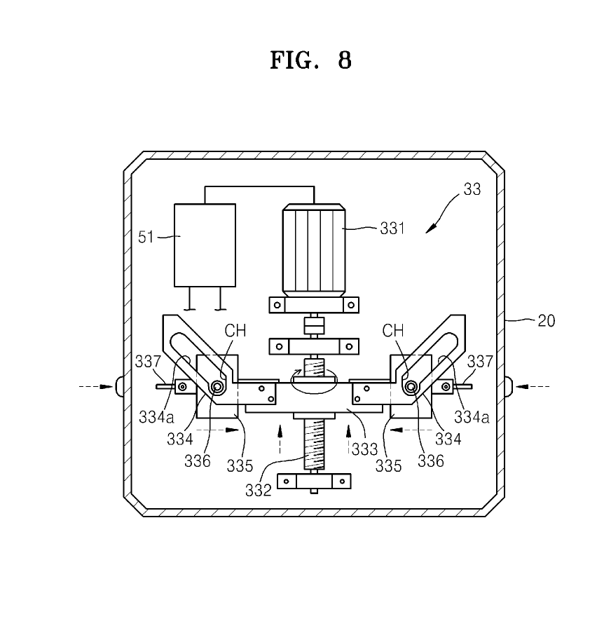

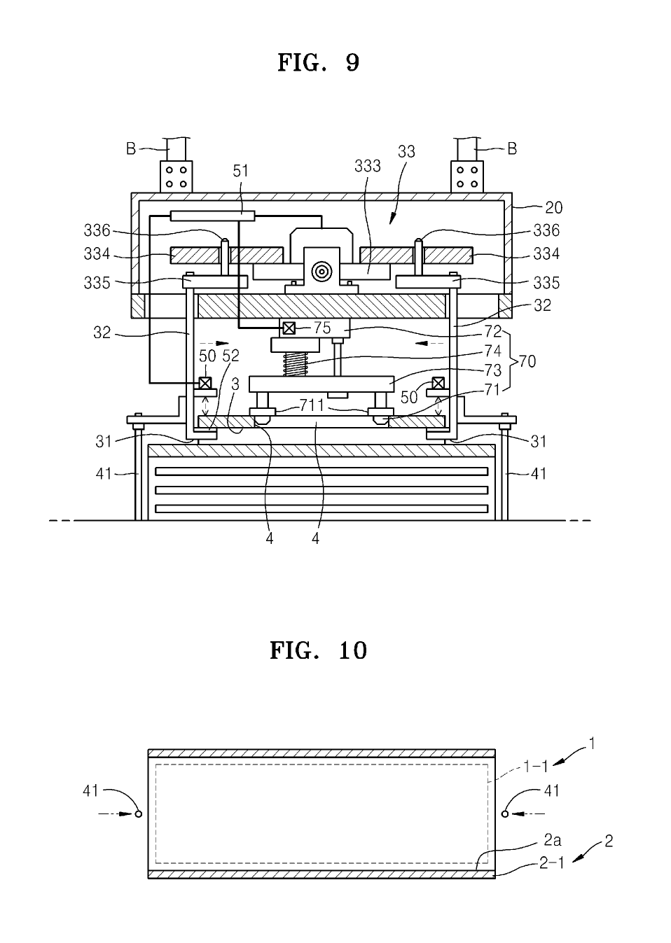

FIG. 2 is a perspective view showing a grip completion state of the hoist apparatus 100 and the hoist system 1000 of FIG. 1. FIG. 8 is a cross-sectional view showing a grip completion state of the grip driving device 33 of FIG. 2 taken along a line VIII-VIII. FIG. 9 is a cross-sectional view showing the grip completion state of the grip driving device 33 of FIG. 2 taken along a line IX-IX. FIG. 10 is a plan view showing a grip completion state of the separation preventing rod 41 and the accommodating container 2 of the grip driving device 33 of FIG. 2.

As shown in FIGS. 2, and 8 to 10, when the grip driving motor 331 of FIG. 8 reversely rotates the screw rod 332 and the movable body 333 moves backward along the screw rod 332, the guiding surface 334a is moved in a direction toward a pair of the carriages 335 approaching each other while carrying out a cam action by the cam hole CH, and thus, the grip finger 31 connected to the grip arm 32 may move toward the stumbling projection 3, thereby gripping the accommodating container 2.

At this time, as shown in FIG. 9, if the stumbling projection 3 is between the grip sensor 50 and the reflection layer 52, the grip sensor 50 may apply a grip completion state signal to the controller 51, and the controller 51 may apply an ascend control signal to the elevating driving apparatus 60 for lifting up and lowering down the elevating unit 20 by receiving the grip completion state signal.

FIG. 3 is a perspective view showing a traveling state of the hoist apparatus 100 and the hoist system 1000 of FIG. 1.

As shown in FIG. 3, if the elevating unit 20 ascends due to the elevating driving apparatus 60 until the elevating unit 20 reaches the traveling unit 10, the guide pins 21 may be respectively inserted into the guide holes 12 formed in the traveling unit 10, and thus, the elevating unit 20 and the traveling unit 10 may be firmly coupled to each other. In this state, the elevating unit 20 and the traveling unit 10 together may be stably moved to another port without being shaken.

Accordingly, as described above, during movement of the accommodating container 2, the object 1 accommodated in the accommodating container 2 may be rapidly and stably moved to a desired position without being separated from the accommodating container 2 by the separation preventing rod 41, and the object 1 or the accommodating container 2 may be protected from an external impact during the movement of the accommodating container 2.

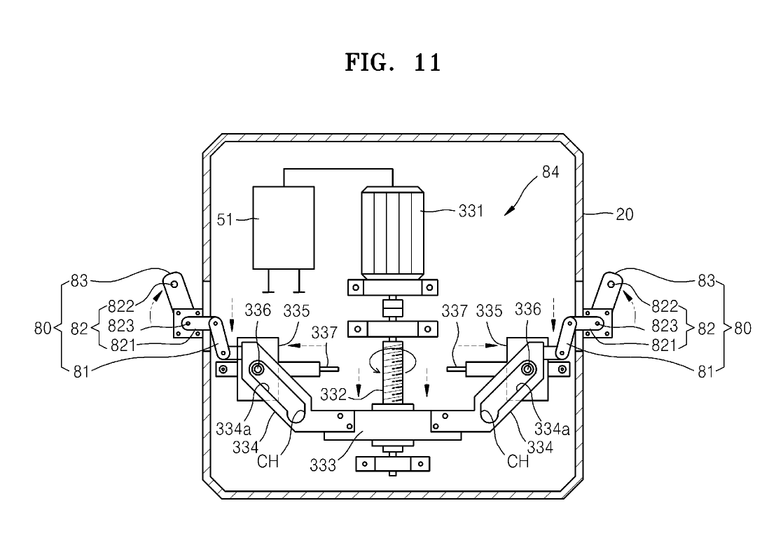

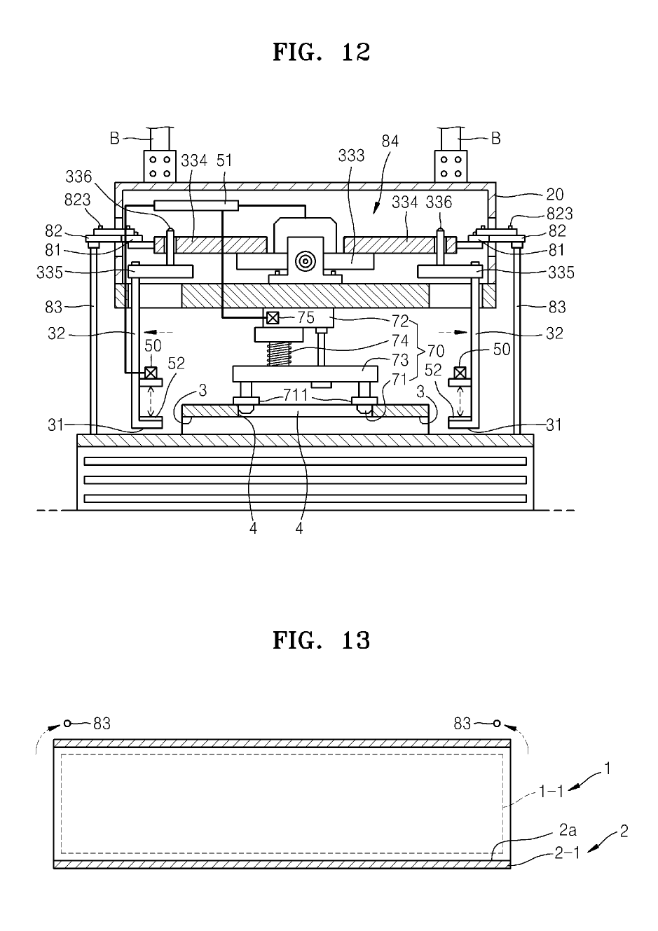

FIG. 11 is a cross-sectional view showing a grip preparation state of a grip driving device 84 of FIG. 5 according to another exemplary embodiment. FIG. 12 is a cross-sectional view showing the grip preparation state of the grip driving device 84 of FIG. 11. FIG. 13 is a plan view showing a grip preparation state of a separation preventing rod 83 and the accommodating container 2 of the grip driving device 84 of FIG. 11.

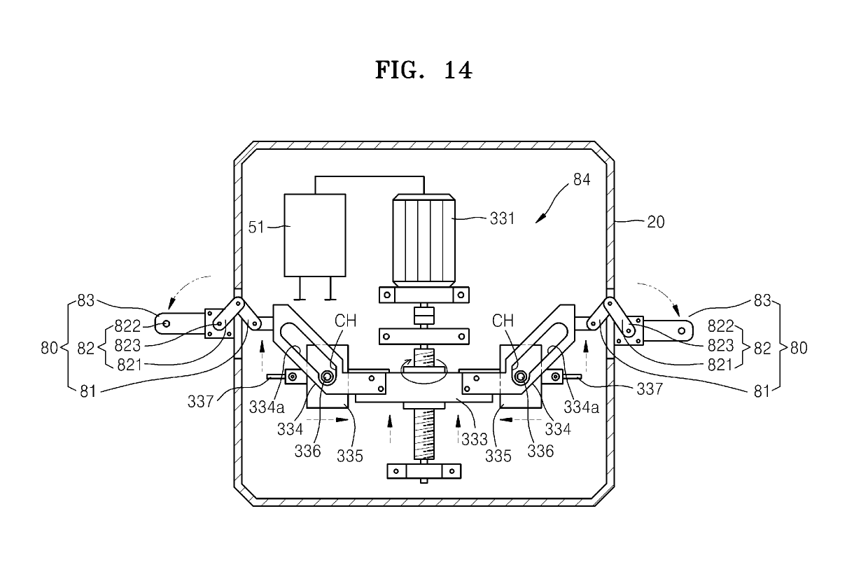

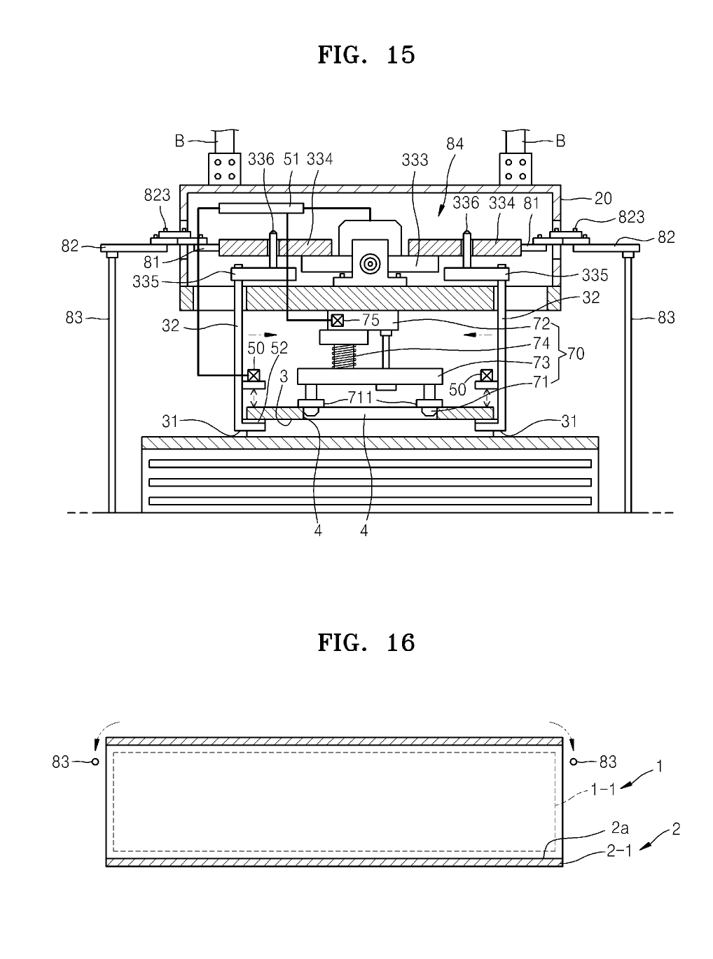

FIG. 14 is a cross-sectional view showing a grip completion state of the grip driving device 84 of FIG. 8 according to another exemplary embodiment. FIG. 15 is a cross-sectional view showing the grip completion state of the grip driving device 84 of FIG. 14. FIG. 16 is a plan view showing a grip completion state of the separation preventing rod 83 and the accommodating container 2 of the grip driving device 84 of FIG. 14.

Meanwhile, instead of the separation preventing apparatus 40 including the separation preventing rod 41 of FIGS. 1 to 10, a separation preventing apparatus 80 including the separation preventing rod 83, which is a rotational type, as shown in FIGS. 11 to 16 may be used.

As shown in FIGS. 11 to 13, the separation preventing apparatus 80 may include a link 81 of which one end is hinge-coupled to the cam member 334, a rotating rod 82 of which one end portion 821 is coupled to another end of the link 81 and another end portion 822 is rotated about a rotation axis 823, and the separation preventing rod 83 installed in the rotating rod 82 and rotated toward the open inlet 2a of the accommodating container 2 by the rotating rod 82.

Accordingly, as shown in FIGS. 11 to 13, if the cam member 334 moves forward due to the grip driving motor 331 in conjunction with movement of the cam member 334, one side of the link 81 moves forward and the other side thereof pulls the one end portion 821 of the rotating rod 82, and thus, the separation preventing rod 83 may be positively rotated in a direction away from the accommodating container 2 as shown in FIG. 13.

On the contrary to this, as shown in FIGS. 14 to 16, if the cam member 334 moves backward due to the grip driving motor 331 in conjunction with movement of the cam member 334, one side of the link 81 moves backward and the other side thereof pushes the one end portion 821 of the rotating rod 82, and thus, the separation preventing rod 83 may be reversely rotated toward the accommodating container 2.

Accordingly, as described above, during movement of the accommodating container 2, the object 1 accommodated in the accommodating container 2 may be rapidly and stably moved to a desired position without being separated from the accommodating container 2 by the separation preventing rod 83, and the object 1 or the accommodating container 2 may be protected from an external impact during the movement of the accommodating container 2.

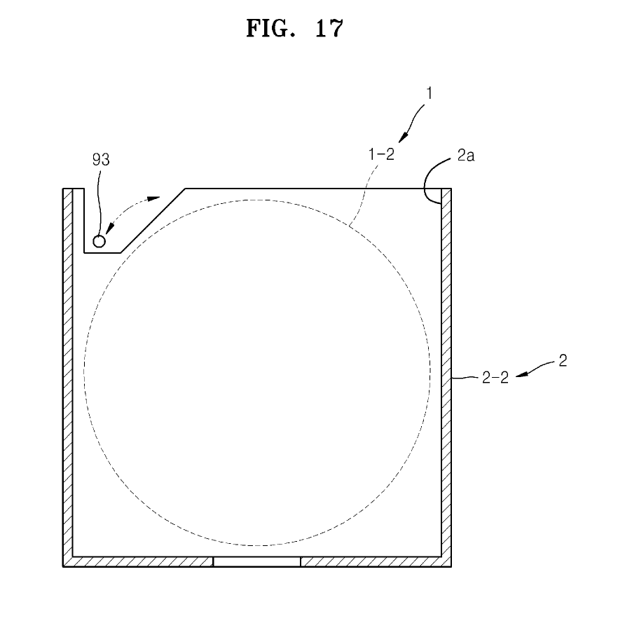

Meanwhile, as shown in FIG. 17, the object 1 may be a ring 1-2 for transferring a semiconductor, and the accommodating container 2 may be a ring cassette 2-2 for accommodating the ring 1-2. Here, the object 1 may be injected into or discharged from the accommodating container 2 through the open inlet 2a of the accommodating container 2, which may be formed at one side of the ring cassette 2-2 as shown in FIG. 17. At this time, as described above, a separation preventing rod 93 may be a direct-acting type separation preventing rod of FIG. 10 or a rotational type separation preventing rod of FIG. 16.

A hoist apparatus and a hoist system including the hoist apparatus can stably, accurately, and automatically transfer a magazine for accommodating a lead frame or a PCB or a ring cassette for accommodating a ring in a semiconductor backend process. Also, the hoist apparatus and the hoist system can allow line automation and factory automation by preventing separation, falling, and an impact of an object to be accommodated, thereby reducing working hours and human power required for the manufacturing process and greatly improving productivity.

While the inventive concept has been particularly shown and described with reference to exemplary embodiments thereof, it will be understood that various changes in form and details may be made therein without departing from the spirit and scope of the following claims.

What is claimed is:

1. A hoist apparatus comprising:
a traveling unit that travels from one place to another;
an elevating unit installed in the traveling unit to be lifted up and lowered down from the traveling unit;
a grip device which is installed in the elevating unit and selectively grips a stumbling projection formed at one side of an accommodating container accommodating an object; and
a separation preventing apparatus which is connected to the elevating unit and selectively closes an open inlet of the accommodating container so that the object accommodated in the accommodating container is not separated from the accommodating container.

2. The hoist apparatus of claim 1, wherein the grip device comprises:
a grip finger formed to have a shape corresponding to the stumbling projection of the accommodating container;
a grip arm connected to the grip finger; and
a grip driving device for selectively moving the grip arm toward the accommodating container.

3. The hoist apparatus of claim 2, wherein the grip driving device comprises:
a grip driving motor installed in the elevating unit;
a screw rod rotated by the grip driving motor;
a movable body which moves forward and backward along the screw rod;
a cam member which is installed at one side of the movable body to move forward and backward together with the movable body and comprises an inclined guiding surface in a direction in which the movable body moves forward and backward; and
a carriage which is installed in the elevating unit to move toward the accommodating container and comprises a rod contacting a guiding surface of the cam member, wherein the grip arm is installed at one side of the carriage.

4. The hoist apparatus of claim 2, wherein the grip device further comprises:
a grip sensor which senses an engagement state between the grip finger and the stumbling projection; and
a controller which receives a grip state signal from the grip sensor and applies a control signal to the elevating driving apparatus for lifting up and lowering down the elevating unit.

5. The hoist apparatus of claim 1, further comprising an aligning device which is installed in the elevating unit and aligns the accommodating container to a regular position.

6. The hoist apparatus of claim 5, wherein the aligning device comprises an aligning protrusion inserted into an aligning hole formed at another side of the accommodating container.

7. The hoist apparatus of claim 6, wherein the aligning device further comprises:
a fixing stage installed in the elevating unit;
an aligning movable stage installed in the fixing stage to be lifted up and lowered down, wherein the aligning protrusion is installed in the aligning movable stage; and;
a spring installed between the fixing stage and the aligning movable stage.

8. The hoist apparatus of claim 5, wherein the aligning device further comprises:
an aligning sensor which senses an alignment state of the elevating unit and the aligning device; and
a controller which receives an alignment state signal from the aligning sensor and applies a control signal to the elevating driving apparatus for lifting up and lowering down the elevating unit.

9. The hoist apparatus of claim 1, further comprising the elevating driving apparatus which is installed in the traveling unit and lifts up and lowers down the elevating unit,
wherein the elevating driving apparatus comprises:
a pulley which winds up a belt installed in the elevating unit; and
an elevating driving motor which rotates the pulley.

10. The hoist apparatus of claim 1, wherein the separation preventing apparatus comprises a separation preventing rod which is fixed at one side of the grip arm connected to the grip finger formed to have a shape corresponding to the stumbling projection of the accommodating container and moves toward the open inlet of the accommodating container together with the grip arm when the grip device grips the stumbling projection.

11. The hoist apparatus of claim 3, wherein the separation preventing apparatus comprises:
a link of which one end is hinge-coupled to the cam member;
a rotating rod of which one end portion is coupled to another end of the link and another end portion is rotated about a rotation axis; and
a separation preventing rod which is installed in the rotating rod and is rotated toward the open inlet of the accommodating container by the rotating rod.

12. The hoist apparatus of claim 1, wherein the object is a lead frame for a semiconductor or a printed circuit board (PCB) for a semiconductor, and the accommodating container is a magazine for accommodating the lead frame or the PCB.

13. The hoist apparatus of claim 1, wherein the object is a ring for transferring a semiconductor, and the accommodating container is a ring cassette for accommodating the ring.

14. The hoist apparatus of claim 1, wherein a guide pin inserted into a guide hole formed in the traveling unit is installed the elevating unit.

15. A hoist system comprising:
a port in which an accommodating container accommodating an object is disposed; and
a hoist apparatus which transfers the accommodating container disposed in the port to another location,
wherein the hoist apparatus comprises:
a traveling unit which travels from one place to another;
an elevating unit installed in the traveling unit to be lifted up and lowered down according to the traveling unit;
a grip device which is installed in the elevating unit and selectively grips a stumbling projection formed at one side of the accommodating container accommodating an object; and
a separation preventing apparatus which is connected to the elevating unit and selectively closes an opened inlet of the accommodating container so that the object accommodated in the accommodating container is not separated from the accommodating container.

16. A hoist apparatus comprising:
an elevating unit connected to a base unit to be lifted up and lowered down from the base unit;
a grip device extended from the elevating unit to grip a stumbling projection formed at one side of an accommodating container accommodating an object; and
a separation preventing apparatus which selectively closes an open inlet of the accommodating container so that the object accommodated in the accommodating container is not separated from the accommodating container.

17. The hoist apparatus of claim 16, wherein the grip device comprises:
a grip finger formed to have a shape corresponding to the stumbling projection of the accommodating container;
a grip arm connected to the grip finger; and
a grip driving device for selectively moving the grip arm toward the accommodating container.

18. The hoist apparatus of claim 17, wherein the grip driving device comprises:
a grip driving motor installed in the elevating unit;
a screw rod rotated by the grip driving motor;
a movable body which moves forward and backward along the screw rod;
a cam member which is installed at one side of the movable body to move forward and backward together with the movable body and comprises an inclined guiding surface in a direction in which the movable body moves forward and backward; and
a carriage which is installed in the elevating unit to move toward the accommodating container and comprises a rod contacting a guiding surface of the cam member, wherein the grip arm is installed at one side of the carriage.

19. The hoist apparatus of claim 17, wherein the grip device further comprises:
a grip sensor which senses an engagement state between the grip finger and the stumbling projection; and
a controller which receives a grip state signal from the grip sensor and applies a control signal to the elevating driving apparatus for lifting up and lowering down the elevating unit.

20. The hoist apparatus of claim 16, further comprising an aligning device which is installed in the elevating unit and aligns the accommodating container to a regular position.
